(19) United States
(12) Patent Application Publication
(10) Pub. No.: US 2016/0227677 A1
(43) Pub. Date: Aug. 4, 2016

(54) ELECTRIC POWER CONVERTER

(71) Applicant: DENSO CORPORATION, Kariya-city (JP)

(72) Inventors: Naoki HIRASAWA, Kariya-shi (JP); Ryota TANABE, Kariya-shi (JP); Tetsuya MATSUOKA, Kariya-shi (JP); Kazuya TAKEUCHI, Kariya-shi (JP); Akira SAKAMOTO, Kariya-shi (JP)

(73) Assignee: DENSO CORPORATION, Kariya-city (JP)

(21) Appl. No.: 15/010,403

(22) Filed: Jan. 29, 2016

(30) Foreign Application Priority Data
Jan. 29, 2015 (JP) 2015-015204

(51) Int. Cl. H05K 7/20; H01F 27/28; H01F 27/24; H02M 7/00; H01F 27/29

(52) U.S. Cl. CPC H05K 7/20927; H02M 7/003; H01F 27/29; H01F 27/24; H01F 27/2823

(57) ABSTRACT

An electric power converter includes a semiconductor module, a reactor having a coil and a core, and a cooler for cooling the semiconductor module and the reactor. The cooler has a coolant passage member having a coolant flow path. The coil of the reactor has an exposed coil portion exposed from the core. The exposed coil portion is in contact with the coolant passage member. The core has a core end face disposed flush with the exposed coil portion, and both the exposed coil portion and the core end face are in surface contact with the coolant passage member.

### CROSS-REFERENCE TO RELATED APPLICATION

This application is based on and claims the benefit of priority from earlier Japanese Patent Application No. 2015-15204 filed Jan. 29, 2015, the description of which is incorporated herein by reference.

### TECHNICAL FIELD

The present disclosure relates to an electric power converter having a semiconductor module and a reactor.

### BACKGROUND

An electric power converter, which generates power for driving a hybrid car or an electric vehicle, for example, has a reactor constituting a booster circuit for boosting a power supply voltage.

With the increase of the current supplied to the electric power converter, heat generation of not only semiconductor modules but the reactor tends to increase.

Therefore, an electric power converter provided with a cooler for cooling a reactor with semiconductor modules has been proposed (refer to Japanese Patent Application Laid-Open Publication No. 2014-138012, for example).

However, a coil of the reactor is embedded in a core in the electric power converter disclosed in the Publication No. '012.

That is, the coil is covered with the core.

Thus, although the reactor is in contact with the cooler, the core is interposed between the coil and the cooler.

Hence, the coil that is a main heat source of the reactor is difficult to cool efficiently.

As a result, there is a problem that it is difficult to improve the heat dissipation efficiency of the reactor.

SUMMARY OF THE DISCLOSURE

An embodiment provides an electric power converter having excellent cooling efficiency of a reactor.

An electric power converter in a first aspect includes a semiconductor module having a built-in semiconductor element therein, a reactor having a coil made of a conductor and a core, which is made of a magnetic material, that covers at least a portion of an outside of the coil, and a cooler for cooling the semiconductor module and the reactor.

The cooler has a coolant passage member having a coolant flow path, and the coil of the reactor has an exposed coil portion exposed from the core.

The exposed coil portion is in contact with the coolant passage member, the core has a core end face disposed flush with the exposed coil portion, and both the exposed coil portion and the core end face are in surface contact with the coolant passage member.

In the electric power converter mentioned above, the reactor is incorporated in the stacked body in a state of being sandwiched between cooling tubes, which are coolant passage members, from both sides in the stacking direction.

Thereby, it is possible to cool the reactor from both sides in the stacking direction.

In addition, the coil has the exposed coil portions, and the exposed coil portions are in contact with the cooling tubes.

Thereby, the heat of the coils can be dissipated directly to the cooling tubes from the exposed coil portions.

In other words, since it is possible to directly cool the coil that is the main heat source in the reactor by the cooler, it is possible to improve the cooling efficiency of the reactor.

As described above, according to the present disclosure, it is possible to provide an electric power converter having excellent reactor cooling efficiency.

### BRIEF DESCRIPTION OF THE DRAWINGS

In the accompanying drawings:

FIG. 1 shows a plan view of an electric power converter in a first embodiment;

FIG. 2 shows a sectional view taken along a line II-II in FIG. 1;

FIG. 3 shows a perspective view of a stacked body in the first embodiment;

FIG. 4 is a plan view of the stacked body in a state with one of divided core members removing in the first embodiment;

FIG. 5 shows a perspective view of a reactor in the first embodiment;

FIG. 6 shows a exploded perspective view of the reactor in first embodiment;

FIG. 7 is a plan view of a stacked body in a state with one of divided core members removed in a second embodiment; and

FIG. 8 is a plan view of a stacked body in a state with one of divided core members removed in a third embodiment.

### DETAILED DESCRIPTION OF THE PREFERRED EMBODIMENTS

### First Embodiment

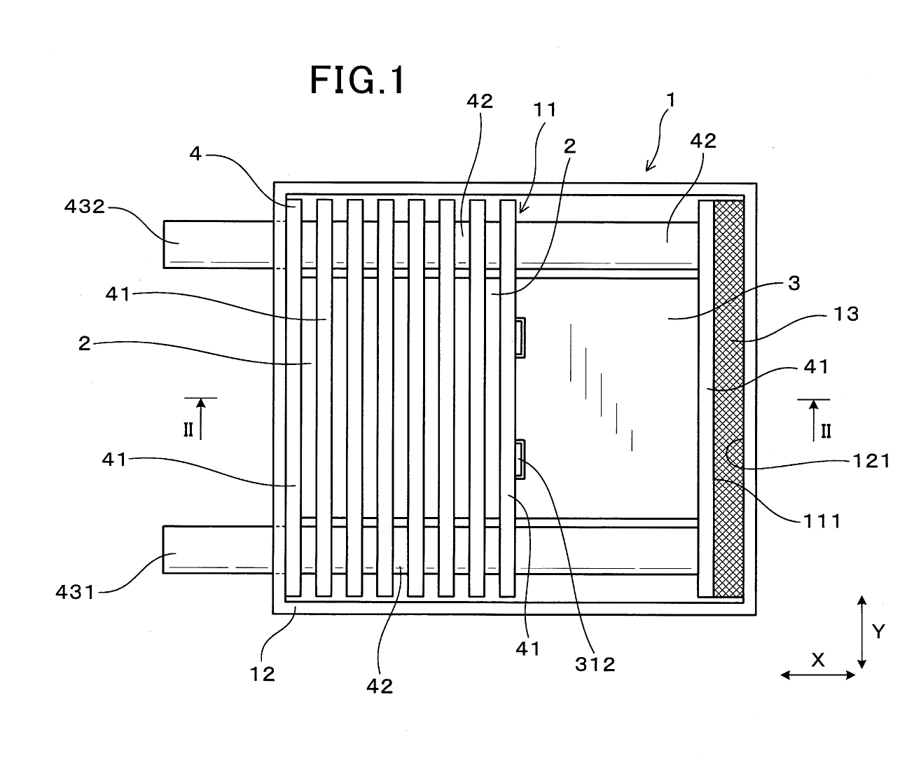

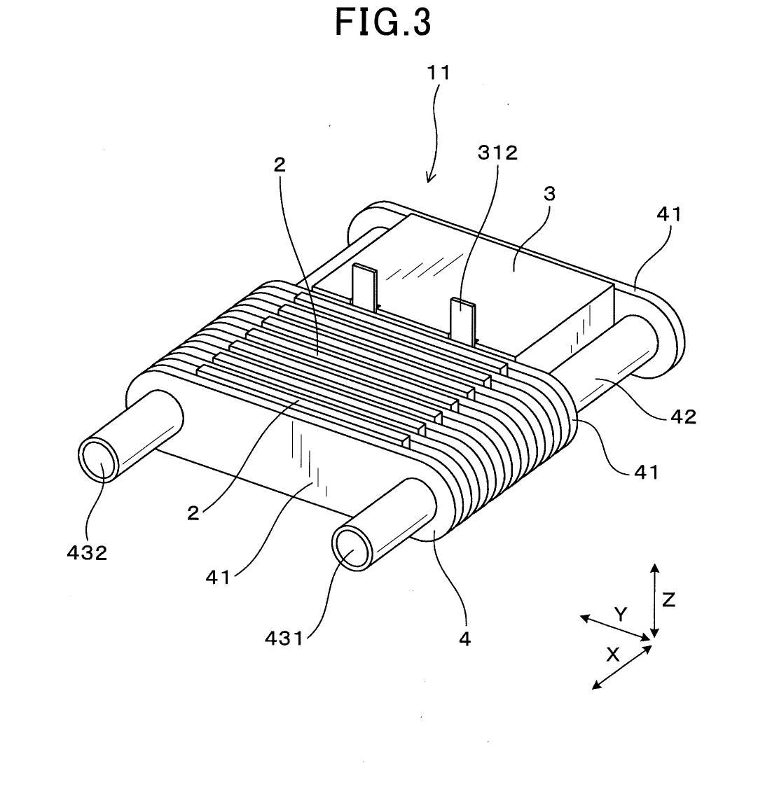

An embodiment of an electric power converter will be described with reference to FIGS. 1 to 6.

As shown in FIGS. 1 to 4, an electric power converter 1 includes semiconductor modules 2 having built-in semiconductor elements therein, a reactor 3 having a coil 31 made of a conductor and a core 32, which is made of a magnetic material, that covers at least a portion of an outside of the coil 31, and a cooler 4 for cooling the semiconductor modules 2 and the reactor 3.

The cooler 4 has a plurality of cooling tubes 41, which are coolant passage members, stacked with the semiconductor modules 2 and the reactor 3.

The respective semiconductor modules 2 and the reactor 3 are sandwiched by the cooling tubes 41 from both sides in a stacking direction X.

A stacked body 11 composed of the semiconductor modules 2, the reactor 3 and the cooling tubes 41 is pressed in the stacking direction X.

The reactor 3 is incorporated into the stacked body 11 in a state where an axial direction Z of the coil 31 is perpendicular to the stacking direction X.

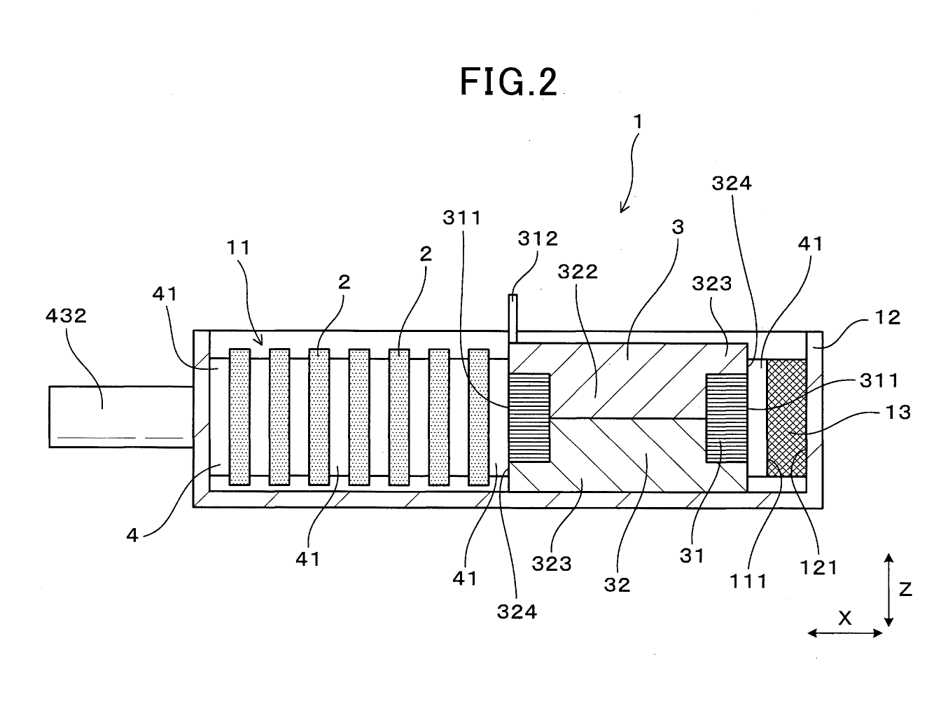

As shown in FIGS. 2, 4, and 5, the coil 31 has exposed coil portions 311 that are exposed at least in one of the stacking directions X from the core 32.

Moreover, the exposed coil portions 311 are in contact with the cooling tubes 41.

That is, the exposed coil portions 311 are in contact with the cooling tubes 41 without an intervention of the core 32.

The exposed coil portions 311 may be in contact with the cooling tubes 41 directly, or may be in contact through members having thermal conductivity.

Further, the coil 31 is formed by winding a conductor wire with an insulating film on its surface, and there exist electrically insulating films on the exposed coil portions 311.

As shown in FIGS. 2, and 4 to 6, the coil 31 has the exposed coil portions 311 on both sides in the stacking direction X.

The core 32 includes outer leg portions 321 disposed on an outer peripheral side of the coil 31, inner leg portions 322 disposed on an inner peripheral side of the coil 31, and base portions 323 that connect the outer leg portions 321 and the inner leg portions 322.

The outer leg portions 321 are disposed at positions in a width direction Y that is perpendicular to both the stacking direction X and the axial direction Z relative to the coil 31.

In the present specification, the stacking direction X and the axial direction Z mean the stacking direction of the stacked body 11 and the axial direction of the coil 3, respectively.

Moreover, the width direction Y means a direction perpendicular to both the stacking direction X and the axial direction Z.

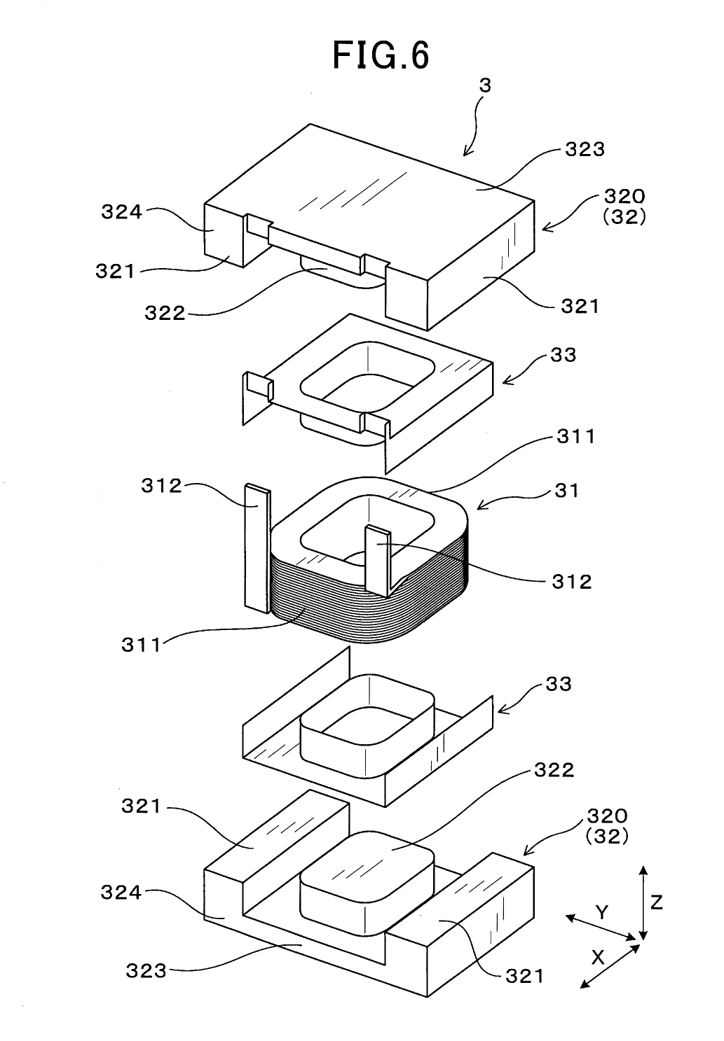

As shown in FIG. 6, the core 32 of the reactor 3 is formed of a pair of divided core members 320 that are divided in the axial direction Z.

In other words, the core 32 is a so-called EE core, and each of the divided core members 320 has a substantially E-shaped cross section that is perpendicular to the stacking direction X of the stacked body 11.

That is, each of the divided core members 320 has a substantially flat plate-like base portion 323, a pair of outer leg portions 321 protruding in the axial direction Z from both ends of the base portion 323, and the inner leg portion 322 protruding from a center of the base portion 323 in the same direction as the outer leg portions 321.

Then, the core 32 is formed by joining the pair of divided core members 320 so as protruding sides of the outer leg portions 321 and the inner leg portions 322 to face each other.

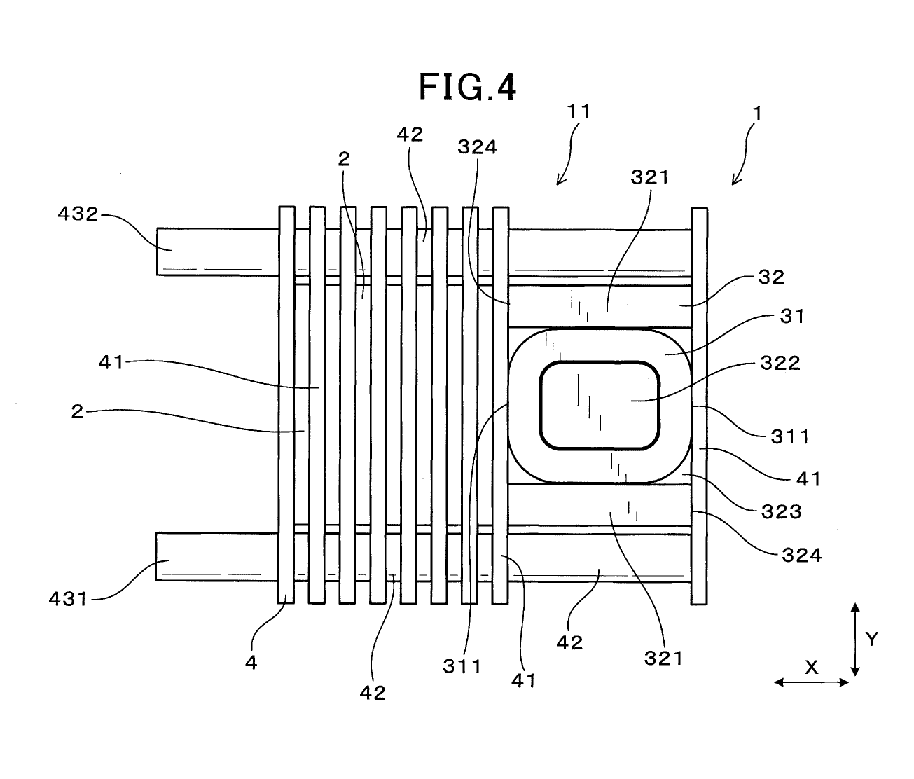

As shown in FIGS. 2 and 4, the core 32 has core end faces 324 disposed flush with the exposed coil portions 311, and both the exposed coil portions 311 and the core end faces 324 are in surface contact with the cooling tubes 41.

The core 32 (the divided core members 320) is formed by compacting a soft magnetic powder such as iron powder, for example.

It should be noted that the materials and production method of the core 32 are not particularly limited as long as it is made of a soft magnetic material.

As shown in FIG. 6, the coil 31 is formed by winding a rectangular conductor helically in a state that a major surface of the conductor faces the axial direction Z.

In other words, the coil 31 is wound in a so-called edge-wise winding.

In addition, the rectangular conductor is formed by forming an insulating film such as enamel on a surface thereof.

Further, the coil 31 is formed by forming a flat surface on each end face of the coil 31 in the stacking direction X, and these flat surfaces are the exposed coil portions 311.

Moreover, another flat surface is formed on each end face of the coil 31 in the width direction Y.

As shown in FIG. 4, a length of the coil 31 in the stacking direction X is larger than a length of the coil 31 in the width direction Y.

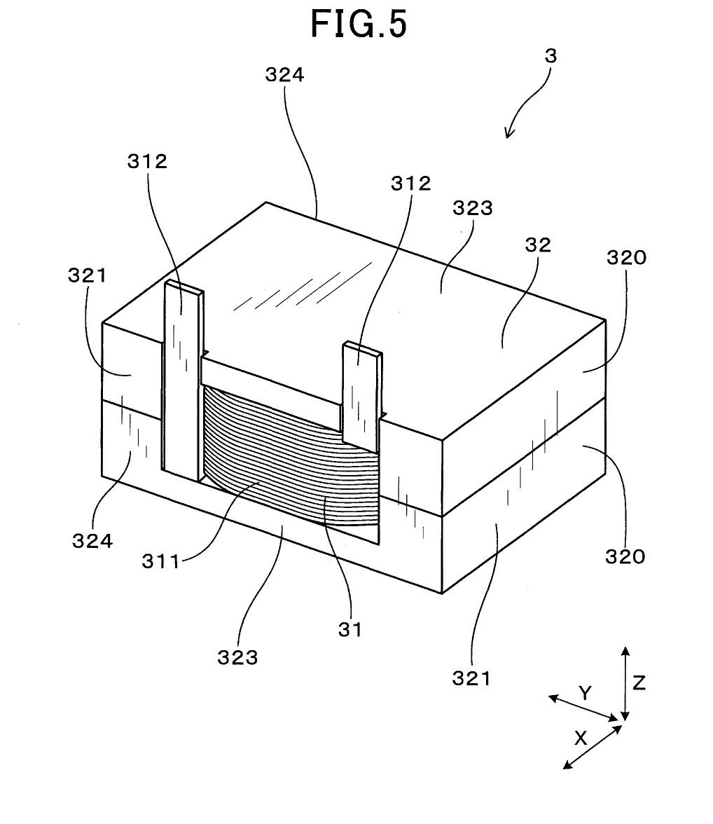

Moreover, as shown in FIGS. 5 and 6, the coil 31 has a pair of terminals 312 protruding in the same direction in the axial direction Z.

As shown in FIGS. 1 to 3, the pair of terminals 312 are drawn out from a side of the coil 31 closer to the semiconductor modules 2.

As shown in FIGS. 2 and 4, the coil 31 is matched with the core 32 in a state in which the inner leg portions 322 of the core 32 are inserted in an inner peripheral side of the coil 31.

In other words, the coil 31 is disposed in a state so as to wound around the inner leg portions 322 of the core 32.

Further, as shown in FIG. 6, insulating members 33 for electrically insulating the coil 31 and the core 32 are interposed between the coil 31 and the core 32.

A pre-molded resin molding as the insulating member 33, for example, may be assembled together with the coil 31 and the core 32.

Moreover, after the matching of the coil 31 and the core 32, a liquid resin may be filled and solidified in a gap between the coil 31 and the core 32.

Furthermore, the insulating member 33 may also be other aspects such as an insulating paper, for example.

The insulating members 33 are disposed in a state of being in contact with the coil 31 and the core 32.

Then, at least in the stacking direction X, the coil 31 abuts the inner leg portions 322 via the insulating members 33, and is configured such that a load in the stacking direction X is transmitted between the coil 31 and the inner leg portions 322.

As shown in FIGS. 1 to 4, the cooler 4 is formed by stacking a plurality of cooling tubes 41 and each of them are connected to each other by connecting pipes 42 in vicinities of both end portions of the cooling tube 41 in the width direction Y.

Further, a coolant inlet pipe 431 for introducing a coolant to the cooler 4 and a coolant outlet pipe 432 for discharging the coolant from the cooler 4 are disposed at one end of the cooler 4 in the stacking direction X.

A side in which the coolant inlet pipe 431 and the coolant outlet pipe 432 are disposed is referred to as a front of the cooler 4 (stacked body 11) and an opposite side as a rear for the sake of convenience in the various embodiments.

The stacked body 11 is formed by disposing the semiconductor modules 2 respectively to a plurality of gaps formed between the plurality of cooling tubes 41 in the cooler 4.

Among the gaps between the cooling tubes 41 in the cooler 4, the reactor 3 is disposed in the rearmost gap.

The gap where the reactor 3 is disposed has a larger length in the stacking direction X than the gaps where the semiconductor modules 2 are disposed.

Therefore, the connecting pipes 42 connecting the cooling tubes 41 sandwiching the reactor 3 are longer than the other connecting pipes 42.

As shown in FIGS. 2 and FIG. 4, the reactor 3 is in surface contact with the pair of cooling tubes 41 at a pair of exposed coil portions 311 and a pair of core end faces 324, respectively.

In other words, cooling surfaces of the cooling tubes 41, which are flat surfaces, are in surface contact with both the exposed coil portions 311 and the core end surface 324 that are flush flat surfaces.

Then, the cooling tubes 41, and the exposed coil portions 311 and the core end faces 324 are in close contact in a state of being pressed in the stacking direction X to each other.

In addition, the semiconductor modules 2 and the cooling tubes 41 are also being pressed in a state of surface contacting with each other.

The coolant introduced from the coolant inlet pipe 431 passes through the connecting pipes 42 y and is distributed to each cooling tube 41, and flows in a longitudinal direction of the cooling tube 41 through coolant flow paths inside the cooling tube 41 (i.e., in the width direction Y).

Then, while flowing through the cooling tubes 41, the coolant exchanges heat with the semiconductor modules 2 and the reactor 3.

The coolant of which the temperature is raised by the heat exchange passes through the connecting pipes 42 on a downstream side appropriately and is guided to the coolant outlet pipe 432, the discharged from the cooler 4.

As for the coolant, for example, a natural coolant such as ammonia or water, water mixed with ethylene glycol-based antifreeze, a fluorocarbon-based coolant such as FLUORINERT (registered trademark), another fluorocarbon-based coolant such as HCFC123 or HFC134a, a methanol, an alcohol-based coolant such as an alcohol, or a ketone-based coolant such as acetone can be used.

As shown in FIGS. 1 and 2, the stacked body 11 is pressed in the stacking direction X.

That is, the electric power converter 1 is formed by disposing the stacked body 11 in the case 12, and disposing a pressing member 13 at a rear end side of the stacked body 11.

The pressing member 13 is pressing a rear end face 111 of the stacked body 11 in the stacking direction X toward the front.

The pressing member 13 is, for example, a leaf spring, and is interposed between the rear end face 111 of the stacked body 11 and an inner wall surface 121, which faces the rear end surface 111, of the case 12 in a state of being compressed elastically deformed in the stacking direction X.

Note that the manner of construction or arrangement of the pressing member 13 is not particularly limited.

The electric power converter 1 is mounted on an electric vehicle or a hybrid vehicle, and is used as an inverter for converting a source power to a driving power required for driving a motor, for example.

Next, functions and effects of the present embodiment will be described.

In the electric power converter 1, the reactor 3 is incorporated in the stacked body 11 in a state where being sandwiched between the cooling tubes 41 from both sides in the stacking direction X.

Thereby, it is possible to cool the reactor 3 from both sides in the stacking direction X.

In addition, the coil 31 has the exposed coil portions 311, and the exposed coil portions 311 are in contact with the cooling tubes 41.

Thereby, the heat of the coils 31 can be dissipated directly to the cooling tubes 41 from the exposed coil portions 311.

In other words, since it is possible to directly cool the coil 31 that is the main heat source in the reactor 3 by the cooler 4, it is possible to improve the cooling efficiency of the reactor 3.

In addition, the coil 31 has the exposed coil portions 311 on both sides in the stacking direction X.

Thus, it is possible to perform the heat dissipation of the coil 31 efficiently from both sides in the stacking direction X.

In addition, the pressing force (sandwiching force) from the pair of cooling tubes 41 that sandwich the reactor 3 can be received in the coil 31.

In other words, the coil 31 acts in the role of a beam with respect to the pressing force applied to the reactor 3.

In general, it is possible to incorporate the reactor 3 into the stacked body 11 without being reinforced by a separate member particularly by being configured to receive the pressing force by the coil 31 that has a higher strength than the core 32.

As a result, a reduction of the number of parts and a miniaturization can be easily realized.

Further, the core 32 has the outer leg portions 321, the inner leg portions 322, and the base portions 323, and the outer leg portions 321 are disposed at the positions in the width direction Y with respect to the coil 31.

Thereby, the rigidity of the coil 31 in the stacking direction X can also be increased by the inner leg portions 322 disposed inside the coil 31.

As a result, it is possible to improve the strength of the reactor 3 with respect to the pressing force.

In addition, it is possible to sufficiently secure the magnetic circuit of the reactor 3, and thus it is possible to secure a sufficient inductance.

Further, the core 32 has the core end faces 324 disposed flush with the exposed coil portions 311, and both the exposed coil portions 311 and the core end faces 324 are in surface contact with the cooling tubes 41.

This makes it possible to further improve the strength of the reactor 3 with respect to the pressing force in the stacking direction X.

Moreover, since it is possible to dissipate the heat to the cooling tubes 41 also from the core 32 in addition to the coil 31, it is possible to further improve the cooling efficiency of the reactor 3.

As described above, according to the present embodiment, it is possible to provide the electric power converter having excellent reactor cooling efficiency.

### Second Embodiment

It should be appreciated that, in the second embodiment and the subsequent embodiments, components identical with or similar to those in the first embodiment are given the same reference numerals unless otherwise indicated so, and repeated structures and features thereof will not be described in order to avoid redundant explanation.

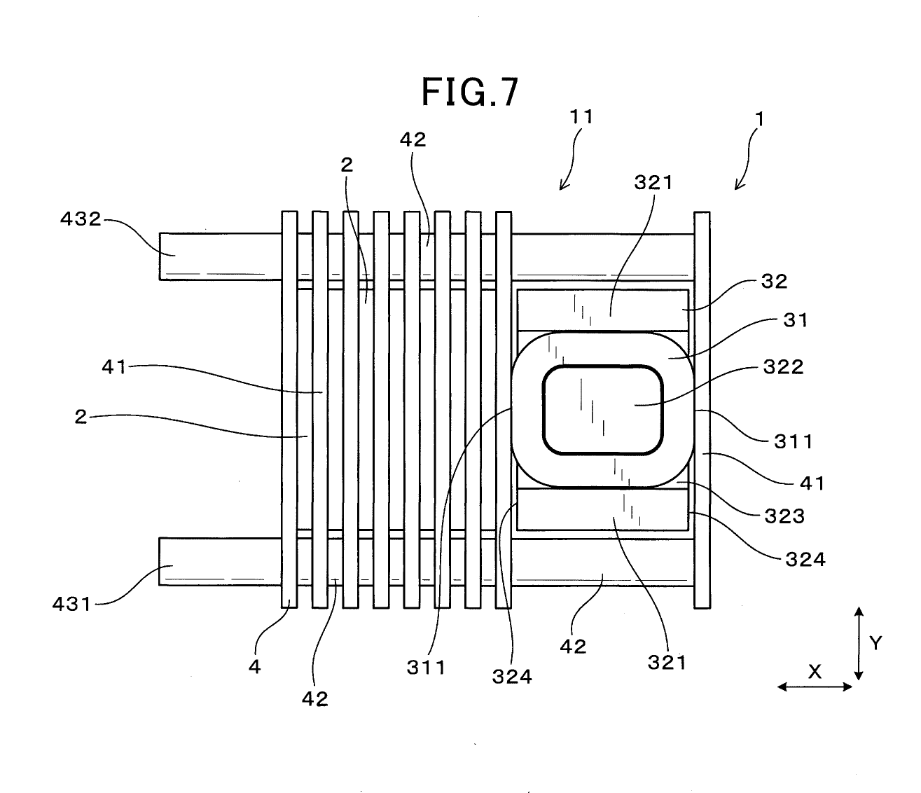

As shown in FIG. 7, the exposed coil portions 311 protrude in the stacking direction X more than the core end surface 324 does in the electric power converter 1 according to the present embodiment.

The pair of exposed coil portions 311 are respectively disposed further away from the outer side than the pair of core end faces 324 are in the stacking direction X.

Then, the reactor 3 is in contact with the cooling tubes 41 at the exposed coil portions 311, while the core end faces 324 are not in contact with the cooling tubes 41.

That is, clearances are formed between the core end surfaces 324 and the cooling tubes 41.

The remainder is the same as the first embodiment.

Since the exposed coil portions 311 protrude in the stacking direction X more than the core end faces 324 do in the present embodiment, the exposed coil portions 311 can be reliably brought into contact with the cooling tubes 41.

In other words, even if there is some lengthal tolerance, the exposed coil portions 311 may be disposed reliably at both ends of the reactor 3 in the stacking direction X.

Then, the pressure from the cooling tubes 41 can be received reliably at the exposed coil portions 311.

As a result, it is possible to reliably improve the cooling efficiency of the reactor 3, and also it is possible to dispose the reactor 3 stably between the cooling tubes 41.

The remainder has the same functions and effects as in the first embodiment.

### Third Embodiment

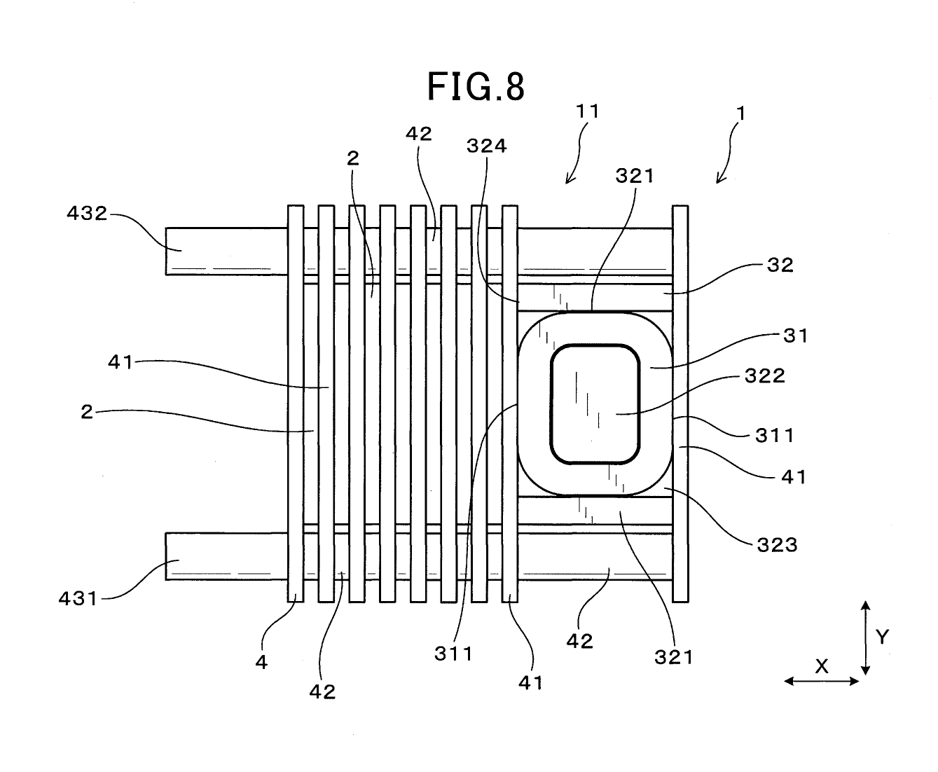

As shown in FIG. 8, the reactor 3 is disposed so that a lateral direction (a short side direction) of the coil 31 is in the stacking direction X when viewed from the axial direction Z in the electric power converter 1 of the present embodiment.

That is, the length of the coil 31 of the reactor 3 in the stacking direction X is shorter than the length of the coil 31 in the width direction Y.

Then, the exposed coil portions 311 are formed on both sides in the lateral direction of the coil 31.

The remainder is the same as first embodiment.

Since the exposed coil portions 311 are formed on both sides in the lateral direction of the coil 31, it is possible to obtain larger areas of the exposed coil portions 311 in the present embodiment.

As a result, heat dissipation of the coil 31, as well as the cooling efficiency of the reactor 3 can be improved.

Moreover, since the exposed coil portions 311 are disposed on both sides in the lateral direction of the coil 31, heat transferring distances from each portion of the coil 31 to the exposed coil portions 311 tend to be shorter.

From this point of view, the heat dissipation of the coil 31, as well as the cooling efficiency of the reactor 3 can be improved.

The remainder has the same functions and effects as in the first embodiment.

The present disclosure is not limited to the above embodiments; however, various modifications are possible within the scope of the present disclosure.

For example, a position at which the reactor in the stacked body is disposed is not limited to the gap at the rear end of the stacked body 11, but may be other positions such as a gap at the front end of the stacked body 11.

What is claimed is:

1. An electric power converter comprising:
a semiconductor module having a built-in semiconductor element therein;
a reactor having a coil made of a conductor and a core, which is made of a magnetic material, that covers at least a portion of an outside of the coil; and
a cooler for cooling the semiconductor module and the reactor; wherein,
the cooler has a coolant passage member having a coolant flow path;
the coil of the reactor has an exposed coil portion exposed from the core;
the exposed coil portion is in contact with the coolant passage member;
the core has a core end face disposed flush with the exposed coil portion; and
both the exposed coil portion and the core end face are in surface contact with the coolant passage member.

2. The electric power converter according to claim 1, wherein,
the cooler has a plurality of the coolant passage members stacked together with the semiconductor module and the reactor; and
a stacked body composed of the semiconductor module, the reactor, and the coolant passage members is pressed in a stacking direction of the stacked body.

3. The electric power converter according to claim 2, wherein,
the coil has the exposed coil portion on both sides in the stacking direction of the coil.

4. The electric power converter according to claim 2, wherein,
the reactor is incorporated into the stacked body in a state where an axial direction of the coil is perpendicular to the stacking direction.

5. The electric power converter according to claim 4, wherein,
the core includes an outer leg portion disposed on an outer peripheral side of the coil, an inner leg portion disposed on an inner peripheral side of the coil, and a base portion that connects the outer leg portion and the inner leg portion; and
the outer leg portion is disposed to be perpendicular to both the stacking direction and the axial direction relative to the coil.

6. The electric power converter according to claim 1, wherein,
a pair of terminals of the coil are disposed at a side of the coil which is closer to the semiconductor module.
